(19) United States
(12) Patent Application Publication
(10) Pub. No.: US 2026/0121644 A1
(43) Pub. Date: Apr. 30, 2026

(54) CLOCK PHASE CALIBRATION DEVICE AND METHOD

(71) Applicant: QUALITAS SEMICONDUCTOR CO., LTD., Seongnam-si, Gyeonggi-do (KR)

(72) Inventors: Changkyung SEONG, Seoul (KR); Chunghyeon CHA, Hwaseong-si (KR)

(73) Assignee: QUALITAS SEMICONDUCTOR CO., LTD., Seongnam-si, Gyeonggi-do (KR)

(21) Appl. No.: 19/117,813

(22) PCT Filed: Sep. 8, 2023
(86) PCT No.: PCT/KR2023/013534

§ 371 Date: Apr. 2, 2025

(30) Foreign Application Priority Data
Oct. 12, 2022 (KR) 10-2022-0130473
Dec. 12, 2022 (KR) 10-2022-0172801

(51) Int. Cl. H03L 7/091

(52) U.S. Cl. CPC H03L 7/091

(57) ABSTRACT

A clock phase calibration device according to one embodiment of the present disclosure for achieving the above-described objects includes: a clock generation module configured to generate a plurality of clocks based on a reference clock; a clock sampling module configured to sample the signal levels of the plurality of clocks and generate sampling data; and a control module configured to adjust the phases of the plurality of clocks based on the sampling data.

### TECHNICAL FIELD

The technical spirit of the present disclosure relates to an electronic device, and more particularly, to a device and method for controlling the phases between clocks to be uniform in a multi-rate clocking method utilizing one or more clocks.

### BACKGROUND ART

The amount of data processed by semiconductor devices widely used in high-performance electronic systems is continuously increasing, and data transmission and reception speeds are being increased by a method of increasing the clock speed or the like. However, the maximum speed is limited due to physical limitations such as circuit speed limits in the process of increasing the clock speed, so that a multi-rate clocking method utilizing one or more clocks instead of increasing the speed of a single clock is applied. In particular, a quarter-rate clocking method, which alternately uses four or eight phases, is widely used in transmission and reception systems of tens of Gb/s or more.

However, phase calibration configured to make the phase intervals between clocks uniform is required to minimize problems that occur due to the non-uniform phase intervals between clocks when a plurality of clocks are used.

### DISCLOSURE

### Technical Problem

The present disclosure has been conceived in response to the above-described background art, and an object of the present disclosure is to provide a device and method for making the phase intervals between a plurality of clocks, used in a multi-rate clocking method, uniform.

An object of the present disclosure is to provide a method capable of determining the phase difference between target clocks by sampling the signal levels of the target clocks.

However, the objects to be accomplished by the present disclosure are not limited to the objects mentioned above, and other objects not mentioned may be clearly understood based on the following description.

### Technical Solution

A clock phase calibration device according to one embodiment of the present disclosure for achieving the above-described objects includes: a clock generation module configured to generate a plurality of clocks based on a reference clock; a clock sampling module configured to sample the signal levels of the plurality of clocks and generate sampling data; and a control module configured to adjust the phases of the plurality of clocks based on the sampling data.

Alternatively, the plurality of clocks may include a first clock and a second clock, and the control module may measure the phase difference between the first and second clocks according to the ratio of the sampling data, in which the signal level of the first clock and the signal level of the second clock correspond to preset conditions, to the sampling data collected based on a sampling clock for a preset period.

Alternatively, the sampling clock and the reference clock may be asynchronous clocks.

Alternatively, the first and second clocks may have a phase difference of 90 degrees.

Alternatively, the control module may determine that the frequency of the sampling clock and the frequency of the reference clock may have an integer multiple relationship with each other when the pattern of the signal level of the first clock and the signal level of the second clock is repeated a preset number of times or more in the sampling data.

Alternatively, the control module may reset the frequency of the sampling clock when it is determined that the frequency of the sampling clock and the frequency of the reference clock have an integer multiple relationship with each other.

Alternatively, the sampling data may include the signal levels of the first and second clocks measured based on the sampling clock for the preset period.

Alternatively, the clock generation module may include a first clock set to have a phase of 0 degrees, a second clock set to have a phase of 90 degrees with respect to the first clock, a third clock set to have a phase of 180 degrees with respect to the first clock, and a fourth clock set to have a phase of 270 degrees with respect to the first clock.

A clock phase calibration method that is performed by a clock phase calibration device according to one embodiment of the present disclosure includes: sampling the signal levels of a first clock and a second clock based on a sampling clock for a preset period and generating sampling data; measuring the ratio of sampling data, in which the signal level of the first clock and the signal level of the second clock correspond to preset conditions, to the sampling data, and determining the phase difference between the first and second clocks based on the measured ratio; and calibrating the phase of the first or second clock based on the phase difference.

Alternatively, the phase of the second clock may be set to have a difference of 90 degrees from the phase of the first clock.

Alternatively, determining the phase difference may include: measuring the ratio of sampling data in which the first clock has a high level and the second clock has a high level; and determining a state in which the measured ratio exceeds a first reference value to be a leading state in which the phase difference between the first and second clocks is smaller than 90 degrees, and determining a case where the measured ratio is smaller than the first reference value to be a lagging state in which a phase difference between the first and second clocks exceeds 90 degrees.

Alternatively, generating the sampling data may include determining that the frequency of the first or second clock has an integer multiple relationship with the frequency of the sampling clock when the pattern of the signal level of the first clock and the signal level of the second clock is repeated a preset number of times or more in the collected sampling data.

Alternatively, generating the sampling data may include resetting the frequency of the sampling clock when it is determined that the frequency of the sampling clock and the frequency of a reference clock have an integer multiple relationship with each other.

### Advantageous Effects

Through the present disclosure, the phases of a plurality of clocks used in a multi-rate clocking method may be corrected such that a desired phase interval is maintained even when the plurality of clocks are out of a set phase interval range.

The present disclosure enables the frequency of a sampling clock for effectively sampling the signal levels of a plurality of clocks, used in a multi-rate clocking method, to be set.

### DESCRIPTION OF DRAWINGS

FIG. 1 is a diagram showing a clock phase calibration system according to one embodiment of the present disclosure;

FIG. 2 is a flowchart illustrating a clock phase calibration method according to one embodiment of the present disclosure;

FIG. 3 is a diagram illustrating the generation of clocks in a clock phase calibration device according to one embodiment of the present disclosure;

FIG. 4 is a diagram illustrating a clock sampling process in a clock phase calibration device according to one embodiment of the present disclosure;

FIG. 5 is a diagram illustrating a clock phase calibration device according to one embodiment of the present disclosure;

FIG. 6 is a flowchart illustrating a method of setting the frequency of a sampling clock in a clock phase calibration process according to one embodiment of the present disclosure; and

FIG. 7 is a diagram illustrating sampling frequencies for respective oscillator control codes according to one embodiment of the present disclosure.

### MODE FOR INVENTION

Embodiments of the present disclosure will be described in detail below with reference to the accompanying drawings so that those having ordinary skill in the art of the present disclosure (hereinafter those skilled in the art) can easily implement the present disclosure. The embodiments presented in the present disclosure are provided to enable those skilled in the art to use or practice the content of the present disclosure. Accordingly, various modifications to embodiments of the present disclosure will be apparent to those skilled in the art. That is, the present disclosure may be implemented in various different forms and is not limited to the following embodiments.

The same or similar reference numerals denote the same or similar components throughout the specification of the present disclosure. Additionally, in order to clearly describe the present disclosure, reference numerals for parts that are not related to the description of the present disclosure may be omitted in the drawings.

The term “or” used herein is intended not to mean an exclusive “or” but to mean an inclusive “or.” That is, unless otherwise specified herein or the meaning is not clear from the context, the clause “X uses A or B” should be understood to mean one of the natural inclusive substitutions. For example, unless otherwise specified herein or the meaning is not clear from the context, the clause “X uses A or B” may be interpreted as any one of a case where X uses A, a case where X uses B, and a case where X uses both A and B.

The term “and/or” used herein should be understood to refer to and include all possible combinations of one or more of listed related concepts.

The terms “include” and/or “including” used herein should be understood to mean that specific features and/or components are present. However, the terms “include” and/or “including” should be understood as not excluding the presence or addition of one or more other features, one or more other components, and/or combinations thereof.

Unless otherwise specified herein or unless the context clearly indicates a singular form, the singular form should generally be construed to include “one or more.”

The term “N-th (N is a natural number)” used herein may be understood as an expression used to distinguish the components of the present disclosure according to a predetermined criterion such as a functional perspective, a structural perspective, or the convenience of description. For example, in the present disclosure, components performing different functional roles may be distinguished as a first component or a second component. However, components that are substantially the same within the technical spirit of the present disclosure but should be distinguished for the convenience of description may also be distinguished as a first component or a second component.

The foregoing descriptions of the terms are intended to help to understand the present disclosure. Accordingly, it should be noted that unless the above-described terms are explicitly described as limiting the content of the present disclosure, they are not used in the sense of limiting the technical spirit of the present disclosure.

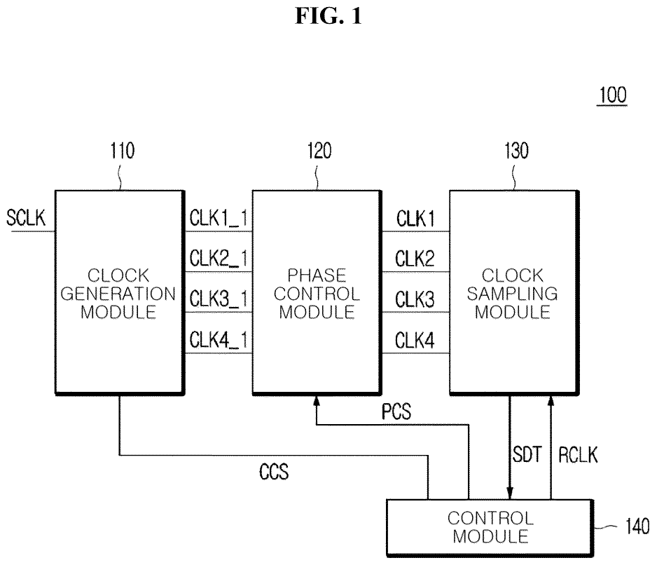

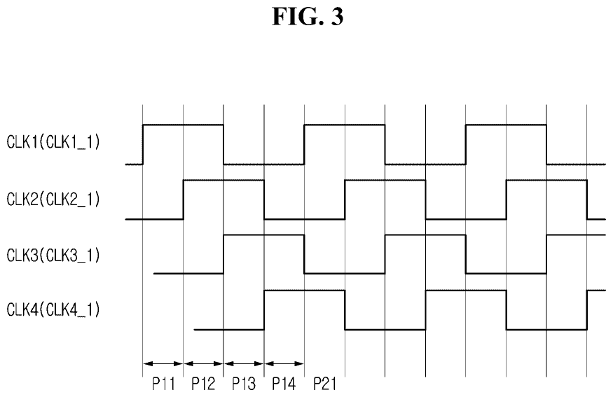

FIG. 1 is a diagram showing a clock phase calibration device according to one embodiment of the present disclosure, and FIG. 3 is a diagram illustrating the generation of clocks in a clock phase calibration device according to one embodiment of the present disclosure.

Referring to FIG. 1, a clock phase calibration device 100 may include a clock generation module 110, a phase control module 120, a clock sampling module 130, and a control module 140. The clock phase calibration device 100 may further include an oscillator (not shown) and a counter (not shown) to sample the signal levels of clocks.

The clock generation module 110 may generate a plurality of clocks based on a reference clock. For example, the clock generation module 110 may generate a plurality of clocks CLK1_1, CLK2_1, CLK3_1, and CLK4_1 by using a source clock SCLK as input. Referring to FIG. 3, the plurality of clocks generated by the clock generation module 110 may include one or more of a first_1 clock CLK1_1, a second_1 clock CLK2_1, a third_1 clock CLK3_1, and a fourth_1 clock CLK4_1.

The plurality of clocks CLK1_1, CLK2_1, CLK3_1, and CLK4_1 may have different phases. The phase differences between the plurality of clocks CLK1_1, CLK2_1, CLK3_1, and CLK4_1 may be uniform or different. For example, the first_1 clock CLK1_1 may be set to have a phase of 0 degrees, the second_1 clock CLK2_1 may be set to have a phase of 90 degrees with respect to the first_1 clock CLK1_1, the third_1 clock CLK3_1 may be set to have a phase of 180 degrees with respect to the first_1 clock CLK1_1, and the fourth_1 clock CLK4_1 may be set to have a phase of 270 degrees with respect to the first_1 clock CLK1_1. The phase differences between the first_1 clock CLK1_1, the second_1 clock CLK2_1, the third_1 clock CLK3_1, and the fourth_1 clock CLK4_1 are each 90 degrees, and the intervals between a first section P11, a second section P12, a third section P13, and a fourth section P14 need to be all uniform, i.e., ¼ UI (unit interval).

Referring back to FIG. 1, the phase control module 120 may adjust the phases of the plurality of clocks CLK1_1, CLK2_1, CLK3_1, and CLK4_1 generated by the clock generation module 110. For example, the phase control module 120 may generate a first clock CLK1 by correcting the phase of the first_1 clock CLK1_1. The phase control module 120 may generate a second clock CLK2, a third clock CLK3, and a fourth clock CLK4 by correcting the phases of the second_1 clock CLK2_1, the third_1 clock CLK3_1, and the fourth_1 clock (CLK4_1), respectively.

For example, the phase control module 120 may include a duty cycle correction circuit (not shown), or may adjust the phases of the plurality of clocks CLK1, CLK2, CLK3, and CLK4 based on a control signal generated by the duty cycle correction circuit. For example, the phase control module 120 may adjust the phases of the plurality of clocks CLK1, CLK2, CLK3, and CLK4 based on a phase control signal PCS generated by the control module 140 or a duty cycle correction control signal.

The clock sampling module 130 may sample the signal levels of the first clock CLK1, the second clock CLK2, the third clock CLK3, and the fourth clock CLK4, which are sampling target clocks, for a preset period based on a sampling clock RCLK. The sampling clock RCLK may be a clock signal asynchronous with the first clock CLK1, the second clock CLK2, the third clock CLK3, and the fourth clock CLK4, or the first_1 clock CLK1_1, the second_1 clock CLK2_1, the third_1 clock CLK3_1, and the fourth_1 clock CLK4_1. For example, the first clock CLK1 may be the same signal as the first_1 clock CLK1_1, or may be a signal in which the phase of the first_1 clock CLK1_1 is corrected. By using an asynchronous clock signal, the phase difference between sampling target clocks may be accurately determined. The reason for this is that a specific pattern can be repeatedly measured when the frequency of the sampling clock RCLK is the same as or an integer multiple of the frequency of the sampling target clocks. The sampling clock RCLK may be generated using a free running oscillator or the like separate from the sampling target clocks.

The control module 140 may control a plurality of clocks by transmitting a clock control signal CCS to the clock generation module 110. The control module 140 may include a free running oscillator for generating a sampling clock RCLK. The control module 140 may reset the appropriate frequency of the sampling clock RCLK based on the sampling data SDT generated by the clock sampling module 130. The clock sampling module 130 may resample the signal levels of the sampling target clocks based on the reset sampling clock RCLK.

The control module 140 may determine the phase differences between the first clock CLK1, the second clock CLK2, the third clock CLK3, and the fourth clock CLK4, which are the sampling target clocks, based on the sampling data SDT generated by the clock sampling module 130, and may generate a phase correction value for the sampling target clocks.

For example, there is assumed and described a case where in the clock generation module 110, the first clock CLK1 is set to have a phase of 0 degrees and the second clock CLK2 is set to have a phase of 90 degrees with respect to the first clock CLK1. In this case, when in the clock sampling module 130, the first clock CLK1 is measured as having a phase of 0 degrees and the second clock CLK2 is measured as having a phase of 90 degrees with respect to the first clock CLK1, the phase correction value of the first clock CLK1 or the second clock CLK2 may be 0. That is, in this case, there is no need to correct the phase of the sampling target clocks. When it is determined that the phase difference between the first clock CLK1 and the second clock CLK2 is larger than or smaller than 90 degrees, the control module 140 may perform control so that the phase difference becomes 90 degrees. More specifically, the control module 140 may set a phase correction value and transmit phase control data (PCS) including the phase correction value to the phase control module 120.

For example, in the case where the number of measurement target clocks is four in a quarter-rate clocking method, the control module 140 may measure the phase difference between the first clock CLK1 and the second clock CLK2 and then correct the phase of the second clock CLK2, may measure the phase difference between the second clock CLK2 and the third clock CLK3 and then correct the phase of the third clock CLK3, and may measure the phase difference between the third clock CLK3 and the fourth clock CLK4 and then correct the phase of the fourth clock CLK4. For example, the control module 140 may correct the phases of a plurality of clocks by applying various algorithms to correct the phases in addition to a method of sequentially correcting the phases of a plurality of clocks. For example, the control module 140 may continuously monitor the phase difference and maintain a desired phase difference even when the phase difference between clocks changes due to an environmental change such as temperature, humidity, or the like.

For example, the control module 140 may be at least one processor included in a semiconductor package. The at least one processor may execute a series of instructions or process signals based on a supply voltage.

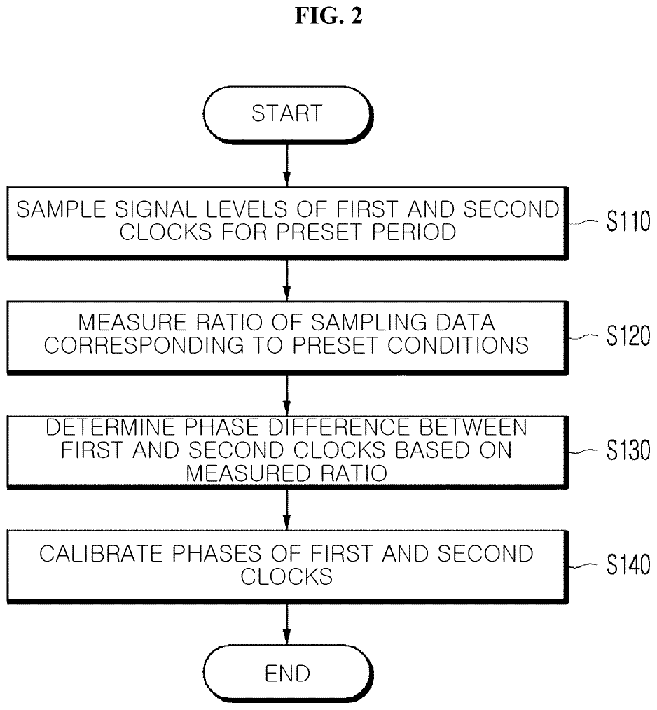

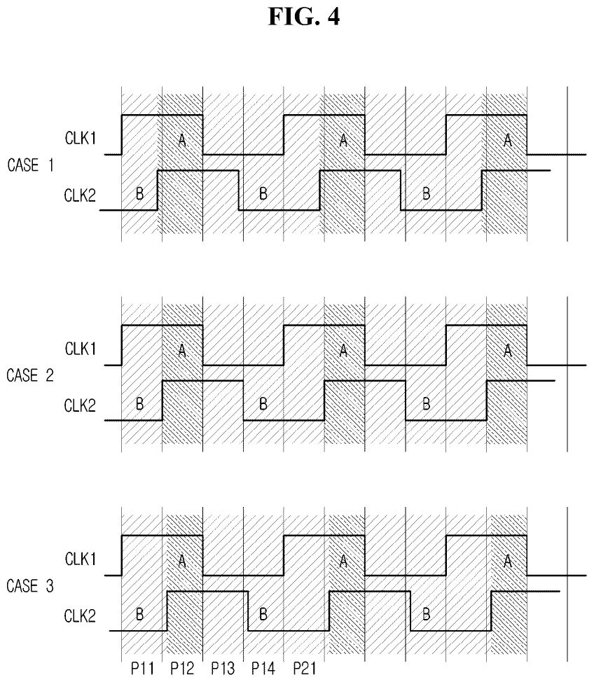

FIG. 2 is a flowchart illustrating a clock phase calibration method according to one embodiment of the present disclosure, and FIG. 4 is a diagram illustrating a clock sampling process in a clock phase calibration device (100) according to one embodiment of the present disclosure.

Referring to FIGS. 1, 2, and 4 together, the clock phase calibration device 100 may sample the signal levels of the first clock (or the first_1 clock) and the second clock (or the second_1 clock) for a preset period based on a sampling clock and generate sampling data in step S110. Although the present disclosure describes a method of calibrating the phase difference between two or four clocks via the clock phase calibration device 100, it is not limited thereto, but may sample various signals and measure and calibrate the phase difference.

For example, the clock phase calibration device 100 may sample the signal levels of the first and second clocks. For example, the first clock may be set to have a phase of 0 degrees, and the second clock can be set to have a phase of 90 degrees with respect to the first clock. However, the first and second clocks may operate at phases different from set phases due to a process or environmental variable.

The clock phase calibration device 100 may measure the signal levels of the first and second clocks based on the sampling clock. The clock phase calibration device 100 may use an asynchronous clock as the sampling clock in order to effectively measure the signal levels of the first and second clocks. For example, the clock phase calibration device 100 may generate the sampling clock asynchronous with the first or second clock by using a free running oscillator or the like. The clock phase calibration device 100 may reset the frequency of the sampling clock when the frequency of the first or second clock is the same as or an integer multiple of the frequency of the sampling clock. The sampling data may be the signal levels of the first and second clocks measured based on the sampling clock for a preset period. The clock phase calibration device 100 may determine the phase difference between the first and second clocks based on the ratio of data satisfying preset conditions to the overall data included in the sampling data.

The clock phase calibration device 100 may measure the ratio of the sampling data, in which the signal level of the first clock and the signal level of the second clock correspond to preset conditions, to the sampling data in step S120. For example, the first clock CLK1 may be set to have a phase of 0 degrees, and the second clock CLK2 may be set to have a phase of 90 degrees with respect to the first clock CLK1. Referring to CASE2 of FIG. 4, when the first and second clocks CLK1 and CLK2, which are 4-phase clocks having a phase difference of 90 degrees, are simultaneously sampled using an asynchronous clock having no frequency relationship, the probability that a signal in region A in which the signal level of the first clock CLK1 is a high level (or 1) and the signal level of the second clock CLK2 is a high level (or 1) is sampled is ¼.

The clock phase calibration device 100 may determine the phase difference between the first and second clocks based on the measured ratio in step S130.

Referring to CASE 1 of FIG. 4, the clock phase calibration device 100 may determine a case where the frequency of the signal in which the signal level of the first clock CLK1 is a high level (or 1) and the signal level of the second clock CLK2 is a high level (or 1) in the overall sampling data obtained by sampling the first and second clocks CLK1 and CLK2 during a preset period is larger than a first reference value or ¼ to be a leading case where the phase difference between the first and second clocks CLK1 and CLK2 is smaller than 90 degrees. The first reference value may be ¼ (or 25%) when the phase difference between the first and second clocks CLK1 and CLK2 is 90 degrees, and may vary depending on detailed conditions.

Referring to CASE 2 of FIG. 4, the clock phase calibration device 100 may determine a case where the frequency of the signal in which the signal level of the first clock CLK1 is a high level (or 1) and the signal level of the second clock CLK2 is a high level (or 1) in the overall sampling data obtained by sampling the first and second clocks CLK1 and CLK2 during the preset period is ¼ to be a case where the phase difference between the first and second clocks CLK1 and CLK2 is equal to 90 degrees.

Referring to CASE 3 of FIG. 4, the clock phase calibration device 100 may determine a case where the frequency of the signal in which the signal level of the first clock CLK1 is a high level (or 1) and the signal level of the second clock CLK2 is a high level (or 1) in the overall sampling data obtained by sampling the first and second clocks CLK1 and CLK2 during the preset period is smaller than ¼ to be a lagging case where the phase difference between the first and second clocks CLK1 and CLK2 is larger than 90 degrees.

Referring back to FIGS. 1 and 2, the clock phase calibration device 100 may calibrate the phase of the first or second clock CLK1 or CLK2 based on the phase difference in step S140. For example, in the case of the leading case (CASE 1), the clock phase calibration device 100 may adjust the phase difference between the first and second clocks CLK1 and CLK2 to 90 degrees by adjusting the phase of the second clock CLK2 in a slower direction. In the case of the lagging case (CASE 3), the clock phase calibration device 100 may adjust the phase difference between the first and second clocks CLK1 and CLK2 to 90 degrees by adjusting the phase of the second clock CLK2 in a faster direction. The clock phase calibration device 100 may repeatedly perform the same calibration operation for the phases of the third and fourth clocks CLK3 and CLK4 after the phases of the first and second clocks CLK1 and CLK2 have been adjusted.

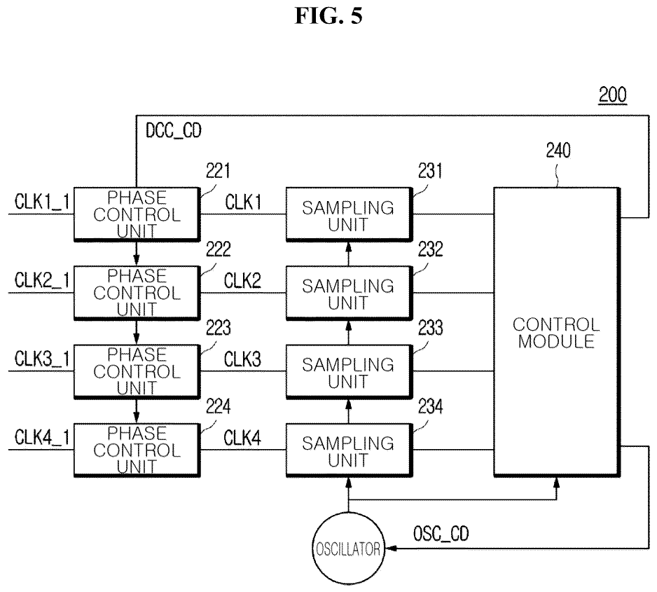

FIG. 5 is a diagram illustrating a clock phase calibration device according to one embodiment of the present disclosure.

Referring to FIG. 5, the clock phase calibration device 200 may include phase control units 221, 222, 223, and 224 corresponding to respective clocks in order to adjust the phases of a plurality of clocks. The clock signals output from the phase control units may be sampled via sampling units 231, 232, 233, and 234 and transmitted to a control module 240.

The control module 240 may generate an oscillator control signal OSC_CD so that an oscillator 250 generates a sampling clock RCLK. The oscillator 250 may supply the sampling clock RCLK to the sampling units 231, 232, 233, and 234. The control module 240 may transmit a duty cycle correction control signal DCC_CD to the phase control units 221, 222, 223, and 224 to adjust the phases of the respective clocks.

The phase control units 221, 222, 223, and 224 perform an operation similar to that of the phase control module 120 of FIG. 1, the sampling units 231, 232, 233, and 234 perform an operation similar to that of the clock sampling module 130 of FIG. 1, and the control module 240 performs an operation similar to that of the control module 140 of FIG. 1. Detailed descriptions thereof will be omitted below.

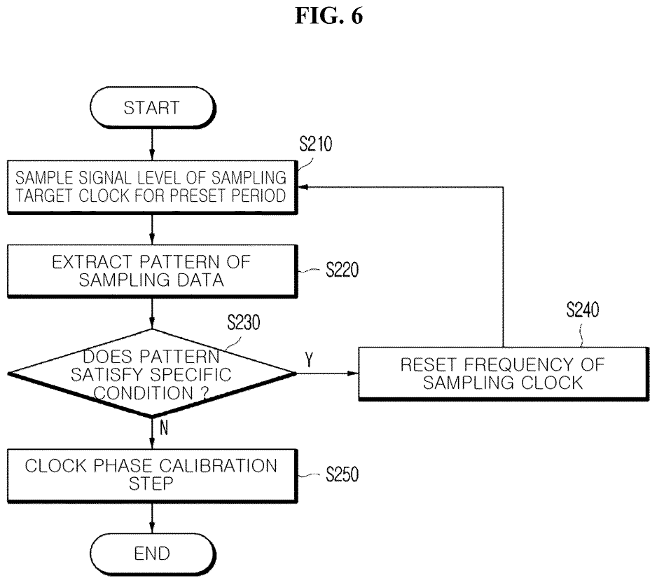

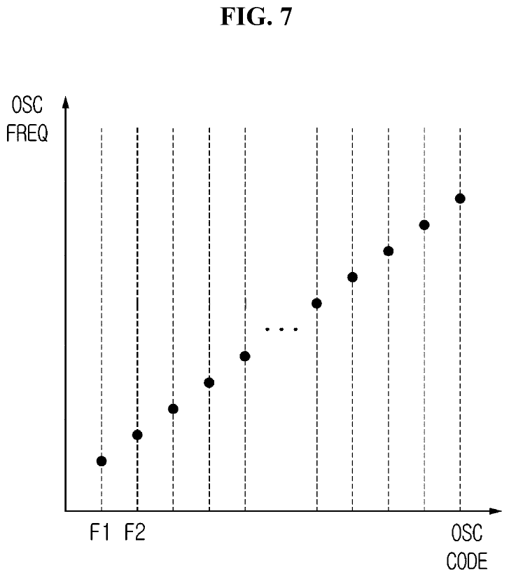

FIG. 6 is a flowchart illustrating a method of setting the frequency of a sampling clock in a clock phase calibration process according to one embodiment of the present disclosure, and FIG. 7 is a diagram illustrating sampling frequencies for respective oscillator control codes according to one embodiment of the present disclosure.

Referring to FIGS. 6 and 4, the clock phase calibration device may sample the signal level of a sampling target clock based on a sampling clock for a preset period and generate sampling data in step S210. For example, the sampling target clock may be the first or second clock CLK1 or CLK2 of FIG. 4.

The clock phase calibration device may extract the pattern of the sampling data in step S220. For example, when the frequency of the first or second clock and the frequency of the sampling clock are the same, only the signal A shown in FIG. 4 may be repeatedly sampled. When the frequency of the first or second clock and the frequency of the sampling clock have an integer multiple relationship with each other, the signal at the same point in time in the operation cycle of the first or second clock is repeatedly sampled, so that the phase difference between the first and second clocks cannot be determined.

The clock phase calibration device determines whether the pattern of the sampling data satisfies a specific condition in step S230. When the specific condition is met, the frequency of the sampling clock may be reset in step S240. For example, the clock phase calibration device may determine that the frequency of the first or second clock and the frequency of the sampling clock are the same as each other or have an integer multiple relationship with each other when the signal A is repeatedly sampled a preset number of times or more. For example, the clock phase calibration device may generate sampling clocks having various frequencies. When it is determined that the frequency of the first or second clock and the frequency of the sampling clock are the same or have an integer multiple relationship, the clock phase calibration device may reset the frequency of a current sampling clock to an adjacent frequency band. Referring to FIG. 7, the clock phase calibration device may adjust the frequency OSC FREQ of the sampling clock by adjusting the oscillator control code OSC CODE (OSC_CD of FIG. 5). The clock phase calibration device may determine whether the frequency of the reset sampling clock is appropriate by repeatedly performing steps S210 to S230.

The clock phase calibration device may terminate the process of setting the frequency of the sampling clock when the pattern of the sampling data does not satisfy the specific condition and then perform the clock phase calibration step described in FIG. 2 based on the currently set sampling clock in step S250.

The clock phase calibration device may accurately measure the phase difference between a plurality of clocks used in a multi-rate clocking method and adjust the phases of clocks through the process of setting the frequency of the sampling clock described in FIG. 6.

The various embodiments of the present disclosure described above may be combined with one or more additional embodiments, and may be changed within the range understandable to those skilled in the art in light of the above detailed description. The embodiments of the present disclosure should be understood as illustrative but not restrictive in all respects. For example, individual components described as unitary may be implemented in a distributed manner, and similarly, the components described as distributed may also be implemented in a combined form. Accordingly, all changes or modifications derived from the meanings and scopes of the claims of the present disclosure and their equivalents should be construed as being included in the scope of the present disclosure.

1. A clock phase calibration device comprising:
a clock generation module configured to generate a plurality of clocks based on a reference clock;
a clock sampling module configured to sample signal levels of the plurality of clocks and generate sampling data; and
a control module configured to adjust phases of the plurality of clocks based on the sampling data.

2. The clock phase calibration device of claim 1, wherein:
the plurality of clocks comprise a first clock and a second clock; and
the control module measures a phase difference between the first and second clocks according to a ratio of sampling data, in which a signal level of the first clock and a signal level of the second clock correspond to preset conditions, to sampling data collected based on a sampling clock for a preset period.

3. The clock phase calibration device of claim 2, wherein the sampling clock and the reference clock are asynchronous clocks.

4. The clock phase calibration device of claim 2, wherein the first and second clocks have a phase difference of 90 degrees.

5. The clock phase calibration device of claim 2, wherein the control module determines that a frequency of the sampling clock and a frequency of the reference clock have an integer multiple relationship with each other when a pattern of the signal level of the first clock and the signal level of the second clock is repeated a preset number of times or more in the sampling data.

6. The clock phase calibration device of claim 5, wherein the control module resets the frequency of the sampling clock when it is determined that the frequency of the sampling clock and the frequency of the reference clock have an integer multiple relationship with each other.

7. The clock phase calibration device of claim 2, wherein the sampling data comprises signal levels of the first and second clocks measured based on the sampling clock for the preset period.

8. The clock phase calibration device of claim 2, wherein the clock generation module comprises a first clock set to have a phase of 0 degrees, a second clock set to have a phase of 90 degrees with respect to the first clock, a third clock set to have a phase of 180 degrees with respect to the first clock, and a fourth clock set to have a phase of 270 degrees with respect to the first clock.

9. A clock phase calibration method, the clock phase calibration method being performed by a clock phase calibration device, the clock phase calibration method comprising:
sampling signal levels of a first clock and a second clock based on a sampling clock for a preset period and generating sampling data;
measuring a ratio of sampling data, in which a signal level of the first clock and a signal level of the second clock correspond to preset conditions, to the sampling data, and determining a phase difference between the first and second clocks based on the measured ratio; and
calibrating a phase of the first or second clock based on the phase difference.

10. The clock phase calibration method of claim 9, wherein the phase of the second clock is set to have a difference of 90 degrees from the phase of the first clock.

11. The clock phase calibration method of claim 10, wherein determining the phase difference comprises:
measuring a ratio of sampling data in which the first clock has a high level and the second clock has a high level; and
determining a state in which the measured ratio exceeds a first reference value to be a leading state in which the phase difference between the first and second clocks is smaller than 90 degrees, and determining a case where the measured ratio is smaller than the first reference value to be a lagging state in which a phase difference between the first and second clocks exceeds 90 degrees.

12. The clock phase calibration method of claim 9, wherein generating the sampling data comprises determining that a frequency of the first or second clock has an integer multiple relationship with the frequency of the sampling clock when a pattern of the signal level of the first clock and the signal level of the second clock is repeated a preset number of times or more in the collected sampling data.

13. The clock phase calibration method of claim 12, wherein generating the sampling data comprises resetting the frequency of the sampling clock when it is determined that the frequency of the sampling clock and a frequency of a reference clock have an integer multiple relationship with each other.
